(19) United States
(12) Patent Application Publication
(10) Pub. No.: US 2024/0306262 A1
(43) Pub. Date: Sep. 12, 2024

(54) Lamp Housing Braze Improvement for Semiconductor Rapid Thermal Processing (RTP) Chamber

(71) Applicant: Applied Materials, Inc., Santa Clara, CA (US)

(72) Inventors: Yao-Hung YANG, Santa Clara, CA (US); Shantanu Rajiv GADGIL, Santa Clara, CA (US); Kaushik RAO, Santa Clara, CA (US); Ngoc LE, Santa Clara, CA (US); Jeffrey Donald OLSON, Castro Valley, CA (US)

(21) Appl. No.: 18/222,979

(22) Filed: Jul. 17, 2023

Related U.S. Application Data
(60) Provisional application No. 63/451,465, filed on Mar. 10, 2023.

(51) Int. Cl. H05B 3/00; B23K 1/19; H05B 3/02

(52) U.S. Cl. CPC H05B 3/0047; B23K 1/19; H05B 3/02

(57) ABSTRACT

Embodiments of lamp housings for a process chamber are provided herein. In some embodiments, a lamp housing for a process chamber includes: a first plate having a plurality of first openings; a copper plate having a plurality of second openings; a plurality of tubes brazed via a braze alloy to the first plate at first ends of the plurality of tubes and brazed to the copper plate via the braze alloy at second ends of the plurality of tubes, wherein the plurality of tubes have central openings that are aligned with the plurality of first openings and the plurality of second openings, and wherein the braze alloy comprises a nickel containing alloy or a copper containing alloy, wherein the copper containing alloy does not include gold; and an annular jacket circumscribing the plurality of tubes and brazed to the first plate via the braze alloy.

### CROSS-REFERENCE TO RELATED APPLICATIONS

This application claims benefit of U.S. provisional patent application Ser. No. 63/451,465, filed Mar. 10, 2023, which is herein incorporated by reference in its entirety.

### FIELD

Embodiments of the present disclosure generally relate to substrate processing equipment.

### BACKGROUND

During rapid thermal processing (RTP) of substrates, thermal radiation is generally used to rapidly heat a substrate in a controlled environment to a maximum temperature of up to about 1350° C. The maximum temperature is maintained for a specific amount of time ranging from less than one second to several minutes depending on the particular process. The substrate is then cooled to room temperature for further processing.

Lamps are commonly used as the source of heat radiation in RTP chambers. Current lamp assembly designs include a lamp body, a bulb, and a base coupled to the lamp body. The lamp assembly is made of components that are typically brazed together. However, conventional brazing material for lamp assemblies is expensive. Additionally, braze joints in conventional lamp assemblies may be prone to forming voids and cracks.

Accordingly, the inventors have provided herein an improved lamp design with reduced cost and improved braze joints.

### SUMMARY

Embodiments of lamp housings for a process chamber are provided herein. In some embodiments, a lamp housing for a process chamber includes: a first plate having a plurality of first openings; a copper plate having a plurality of second openings; a plurality of tubes brazed via a braze alloy to the first plate at first ends of the plurality of tubes and brazed to the copper plate via the braze alloy at second ends of the plurality of tubes, wherein the plurality of tubes have central openings that are aligned with the plurality of first openings and the plurality of second openings, and wherein the braze alloy comprises a nickel containing alloy or a copper containing alloy, wherein the copper containing alloy does not include gold; and an annular jacket circumscribing the plurality of tubes and brazed to the first plate via the braze alloy.

In some embodiments, a lamp housing for a process chamber includes: a first plate made of a first material and having a plurality of first openings; a copper plate having a plurality of second openings; a plurality of tubes brazed via a braze alloy to the first plate at first ends of the plurality of tubes and brazed to the copper plate via the braze alloy at second ends of the plurality of tubes, wherein the plurality of tubes have central openings that are aligned with the plurality of first openings and the plurality of second openings, and wherein the braze alloy comprises a copper containing alloy and does not include gold; and an annular jacket made of the first material and circumscribing the plurality of tubes and brazed to the first plate via the braze alloy and coupled and the copper plate.

In some embodiments, a method of forming a lamp housing for a process chamber includes: placing a braze alloy at a plurality of first interfaces disposed between a first plate of a lamp housing and a plurality of hollow tubes of the lamp housing, at a plurality of second interfaces disposed between a copper plate of the lamp housing and the plurality of hollow tubes, and at a third interface disposed between an annular jacket of the lamp housing disposed about the plurality of hollow tubes and the first plate, wherein the braze alloy comprises a copper containing alloy, wherein the copper containing alloy does not include gold; and heating the braze alloy to join the plurality of hollow tubes to the first plate, the plurality of hollow tubes to the copper plate, and the annular jacket to the first plate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional side view of a rapid thermal processing (RTP) chamber in accordance with at least some embodiments of the present disclosure.

FIG. 2 depicts a partial cross-sectional isometric top view of a lamp housing in accordance with at least some embodiments of the present disclosure.

FIG. 3 depicts a cross-sectional side view of a portion of a lamp housing in accordance with at least some embodiments of the present disclosure.

FIG. 4 depicts a cross-sectional side view of a portion of a lamp housing in accordance with at least some embodiments of the present disclosure.

FIG. 5 depicts a cross-sectional side view of a portion of a lamp housing in accordance with at least some embodiments of the present disclosure.

FIG. 6 depicts a cross-sectional side view of an interface between a jacket of a lamp housing and a copper plate of the lamp housing in accordance with at least some embodiments of the present disclosure.

FIG. 7 depicts a flow chart of a method of forming a lamp housing for a process chamber in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of lamp housings for a process chamber are provided herein. The process chamber may be a rapid thermal processing (RTP) chamber. The lamp housing generally includes a plurality of tubes brazed via a braze alloy to one or more plates and an annular jacket surrounding the plurality of tubes and brazed via the braze alloy to the one or more plates. The one or more plates include a copper plate. The plurality tubes are made of a first material. The braze alloy is generally made of a material that is not susceptible to corrosion when coupled with copper and having a liquidus temperature less than a melting temperature of copper. The braze alloy is advantageously more cost effective than conventional braze alloys for use with lamp housings for RTP chambers. The one or more plates may advantageously include features such as grooves, slots, chamfers, or the like, to improve the integrity of the brazed joints. The braze alloy is generally made of a material that is not susceptible to corrosion when coupled with copper and having a liquidus temperature less than a melting temperature of copper. The braze alloy may be in wire or flat shim form, or a combination thereof. In some embodiments, the braze alloy is formed using 3D printing or additive manufacturing techniques.

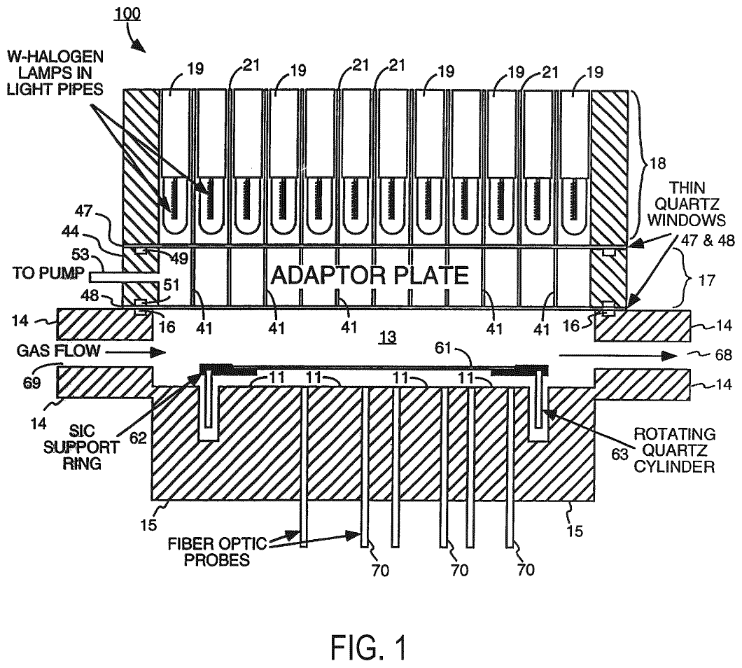

FIG. 1 depicts a schematic cross-sectional side view of a RTP chamber in accordance with at least some embodiments of the present disclosure. The RTP chamber 100, as shown in FIG. 1, generally includes a chamber body having sidewalls 14 and a bottom wall 15 to define an interior volume 13 therein. The sidewalls 14 and the bottom wall 15 are made of a metal, such as stainless steel. An upper portion of the sidewalls 14 is sealed to a window assembly 17 by “O” rings 16. A lamp housing 18 is positioned over and coupled to the window assembly 17. The lamp housing 18 includes a plurality of lamps 19, for example, tungsten halogen lamps, each mounted into a plurality of tubes 21 which can be a stainless steel, brass, aluminum, or other metal.

A substrate 61, for example a wafer, is supported along the edge of the substrate in the interior volume 13 by a substrate support 62 made up of a ceramic material, such as silicon carbide. The substrate support 62 is mounted on a quartz cylinder 63 that is rotatable. By rotating the quartz cylinder 63, the substrate support 62 and the substrate 61 can be rotated. An additional ceramic adapter ring can be used to allow substrates of different diameters to be processed (e.g., 150 mm as well as 200 mm). The outside edge of the substrate support 62 preferably extends less than two inches from the outside diameter of the substrate 61. In some embodiments, the interior volume 13 has a volume of approximately two liters.

The bottom wall 15 of the RTP chamber 100 includes a reflective surface 11 for reflecting energy onto the backside of the substrate 61. In some embodiments, the reflective surface 11 is a gold coated top surface. Additionally, the RTP chamber 100 may include a plurality of fiber optic probes 70 positioned through the bottom wall 15 of the RTP chamber 100 in order to detect the temperature of the substrate 61 at a plurality of locations across the bottom surface of the substrate 61. Reflections between the backside of the substrate 61 and reflective surface 11 create a blackbody cavity which makes temperature measurement independent of substrate backside emissivity and thereby provides accurate temperature measurement capability.

The RTP chamber 100 includes a gas inlet 69 formed through the sidewalls 14 for injecting process gas into the interior volume 13 to allow various processing steps to be carried out in the RTP chamber 100. A gas source such as a tank of oxygen containing gas such as O₂ or a tank of hydrogen containing gas such as H₂ is coupled to the gas inlet 69. Positioned on the opposite side of the gas inlet 69, in the sidewall 14, is a gas outlet 68. The gas outlet 68 is coupled to a vacuum source, such as a pump, to exhaust process gas from the interior volume 13 and to reduce the pressure in the interior volume 13. The vacuum source maintains a desired pressure while process gas is continually fed into the RTP chamber 100 during processing.

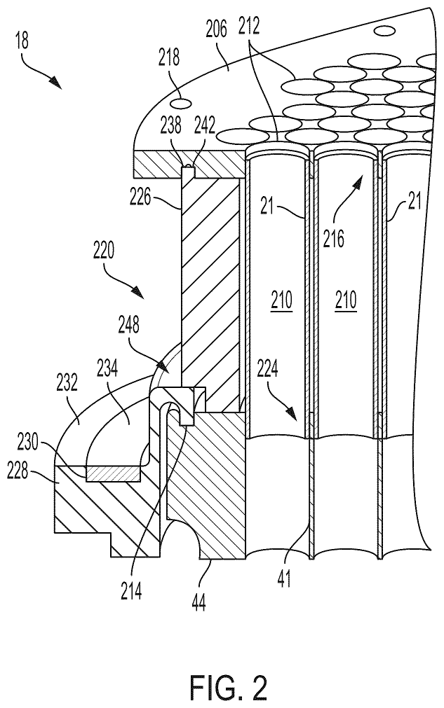

The plurality of lamps 19 may generally include a filament wound as a coil with an axis parallel to the axis of a lamp envelope. Most of the light is emitted perpendicular to the axis towards sidewalls of the surrounding tube of the plurality of tubes 21. The substrate support 62 may be a support ring. The length of the plurality of tubes 21 is selected to be at least as long as the associated lamp. However, the length of the plurality of tubes 21 may be longer than the associated lamp provided that the power reaching the substrate 61 is not substantially attenuated by increased reflection. In some embodiments, the plurality of tubes 21 includes 100 or more tubes. In some embodiments, the plurality of tubes 21 includes 300 or more tubes. In some embodiments, the plurality of tubes 21 are positioned in a hexagonal array or in a “honeycomb shape”, for example, as illustrated in FIG. 2.

The plurality of lamps 19 are positioned to adequately cover an entire surface area of the substrate 61 and the substrate support 62. In some embodiments, the plurality of tubes 21 are grouped in zones, which can be independently controlled to provide for extremely uniform heating of the substrate 61. The plurality of tubes 21 can be cooled by flowing a coolant, such as water, between the various tubes. The lamp housing 18 comprising the plurality of tubes 21 and associated plurality of lamps 19 allows the use of thin quartz windows to provide an optical port for heating the substrate 61 within the RTP chamber 100.

In some embodiments, the lamp housing 18 includes a copper plate 44 having a plurality of second openings 41. In some embodiments, the copper plate 44 is made of oxygen free copper. The plurality of second openings 41 are generally aligned with and brazed to the plurality of tubes 21. In some embodiments, the lamp housing 18 includes one or more quartz plates. For example, the lamp housing 18 may include a quartz plate 48 coupled to the copper plate 44. In some embodiments, the lamp housing 18 includes a quartz plate 47 disposed between the copper plate 44 and the plurality of tubes 21. In some embodiments, the quartz plates 47, 48 may be sealed with “O” rings 49 and 51 near the copper plate 44 and/or the sidewalls 14. In some embodiments, a vacuum can be produced in the plurality of second openings 41 by pumping through a tube 53.

The RTP chamber 100 is generally a single substrate reaction chamber capable of ramping the temperature of a substrate 61 at a rate of 25-100° C./sec. The RTP chamber 100 is said to be a “cold wall” reaction chamber because the temperature of the substrate 61 during the oxidation process is at least 400° C. greater than the temperature of chamber sidewalls 14. Heating/cooling fluid can be circulated through the sidewalls 14 and/or bottom wall 15 to maintain walls at a desired temperature. In some embodiments, the RTP chamber 100 is configured as part of a “cluster tool” which includes a load lock and a transfer chamber with a robotic arm. In some embodiments, the RTP chamber 100 is configured as a stand-alone tool.

FIG. 2 depicts a partial cross-sectional isometric top view of a lamp housing 18 in accordance with at least some embodiments of the present disclosure. The lamp housing 18 includes a top plate 206, such as a first plate, that is made of a first material. The top plate 206 includes a plurality of first openings 212. The lamp housing 18 includes a plurality of tubes 21 that are brazed via a braze alloy to the top plate 206 at upper ends 216, such as first ends, of the plurality of tubes 21. Lower ends 224, such as second seconds, of the plurality of tubes 21 are brazed to the copper plate 44 via the braze alloy. The copper plate 44 includes the plurality of second openings 41. The plurality of tubes 21 have central openings 210 that are aligned with the plurality of first openings 212 of the top plate 206 and the plurality of second openings 41 of the copper plate 44. In some embodiments, the plurality of tubes 21 are made of the first material. In some embodiments, the first material does not include copper. In some embodiments, the first material is stainless steel.

The lamp housing 18 includes an annular jacket 220 circumscribing the plurality of tubes 21 and brazed to the top plate 206 via the braze alloy. In some embodiments, the annular jacket 220 is made of the first material. The annular jacket 220 facilitates the flow to coolant within the annular jacket 220 and between the various tubes of the plurality of tubes 21 to cool the tubes. In some embodiments, the annular jacket 220 includes an annular ring 226 and a bottom flange 228. The bottom flange 228 is disposed about the copper plate 44 and coupled to the copper plate 44. The bottom flange 228 facilitates coupling the lamp housing 18 to, for example, the sidewalls 14. In some embodiments, an upper surface 232 of the bottom flange 228 includes an annular recess 230. A top ring 234 may be disposed in the annular recess 230 to cover any openings in the annular recess 230 configured to enable coupling the bottom flange 228 to the sidewalls 14.

In use, when heated, the braze alloy liquifies to fill a desired joint between multiple parts and subsequently joins the multiple parts when the liquified braze alloy is cooled. In some embodiments, the braze alloy comprises a nickel containing alloy or a copper containing alloy, where the copper containing alloy does not include gold. In some embodiments, the braze alloy comprises one of: a titanium-nickel alloy, a silver-copper-tin-titanium alloy, a silver-copper-indium-titanium alloy, a copper-manganese-nickel alloy, a copper-germanium-nickel alloy, a silver-copper-lead alloy, or a gold-nickel alloy. A gold-nickel alloy, while more costly than the other aforementioned braze alloy materials, has beneficial wettability and fluidity characteristics that reduce delamination and voids within the brazed joints.

In some embodiments, the braze alloy comprises a copper alloy that does not include gold. In some embodiments, the braze alloy does not include materials that cause corrosion when combined with copper, such as iron, carbon, zinc, lead, or aluminum. In some embodiments, the braze alloy is a copper-germanium alloy. For example, the braze alloy may be a copper-germanium-nickel alloy having, by weight, about 60 to about 90 percent copper, about 5 to about 40 percent germanium, and about 0.1 to about 0.5 percent nickel. In some embodiments, the braze alloy is a silver-copper-tin-titanium alloy having, by weight, about 50 to about 70 percent silver, about 25 to about 45 percent copper, about 0.5 to about 2 percent tin, and about 1 to about 3 percent titanium. In some embodiments, the braze alloy is a silver-copper-indium-titanium alloy having, by weight, about 50 to about 70 percent silver, about 20 to about 40 percent copper, about 10 to about 15 percent indium, and about 0.5 to about 3 percent titanium.

In some embodiments, the top plate 206 includes an annular groove 238 to accommodate an upper lip 242 of the annular jacket 220. In some embodiments, an upper surface of the copper plate 44 includes an annular groove 214 to accommodate an inner lip 248 of the bottom flange 228. In some embodiments, the top plate 206 includes openings 218 disposed about the top plate 206 to facilitate coupling the top plate 206 to other components of the RTP chamber 100.

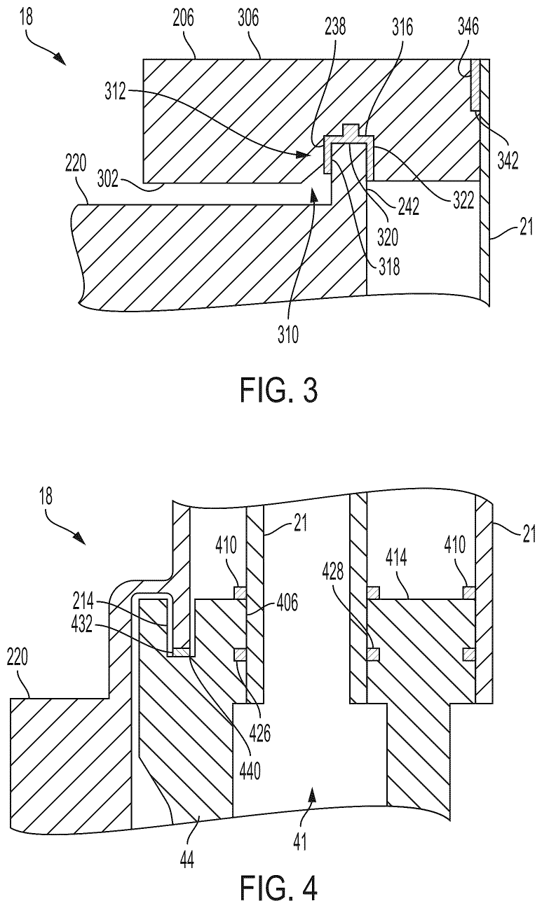

FIG. 3 depicts a cross-sectional side view of a portion of a lamp housing 18 in accordance with at least some embodiments of the present disclosure. In some embodiments, a lower surface 302 of the top plate 206 includes a chamfer 310 adjacent to an interface 312 between the annular jacket 220 and the top plate 206. In some embodiments, a braze alloy 316 is disposed between the annular jacket 220 and the top plate 206. In some embodiments, the braze alloy 316 is a part that extends along an outer sidewall 318 of the upper lip 242, a top surface 320 of the upper lip 242, and an inner sidewall 322 of the upper lip 242.

In use, when heated, the braze alloy 316 liquifies to fill the joint between the upper lip 242 and the annular groove 238 of the top plate 206 and subsequently joins the upper lip 242 to the top plate 206 when the liquified braze alloy 316 is cooled. The chamfer 310 may advantageously promote capillary action when the braze alloy 316 is heated and enhance the brazed joint integrity and reduce voids. A braze alloy 346 may be disposed about each of the plurality of tubes 21 for coupling the plurality of tubes 21 to the top plate 206. In some embodiments, the braze alloy 346 is disposed at least partially in an annular slot 342 formed adjacent an upper surface 306 of the top plate 206 for each of the plurality of tubes 21.

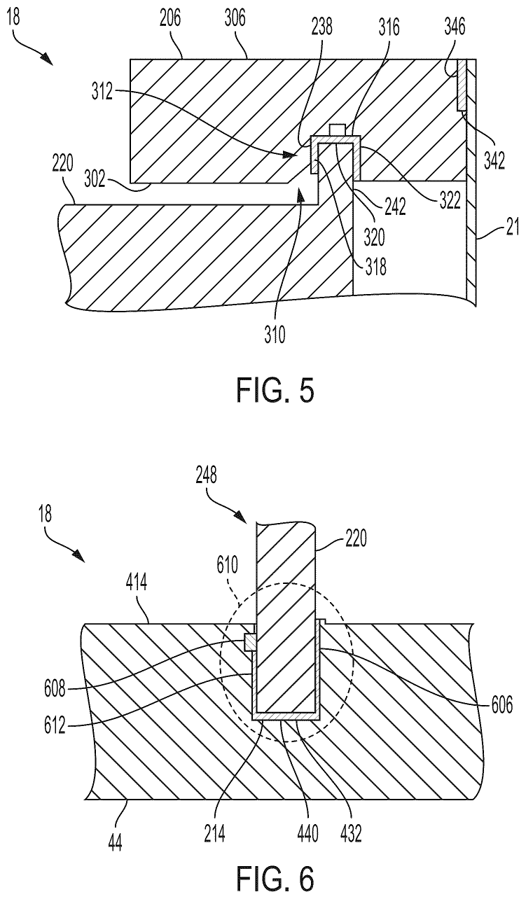

In some embodiments, as depicted in FIG. 3, the braze alloy 316 may be a part that is 3D printed based on actual dimensions of a gap between the upper lip 242 and the annular groove 238. For example, the braze alloy 316 that is 3D printed may have sidewalls that vary in wall thickness to accommodate different dimensions of a gap between the inner sidewall 322 of the upper lip 242 and an opposing sidewall of the annular groove 238. In some embodiments, as depicted in FIG. 5, the braze alloy 316 may be in wire or flat shim form, where the wire or flat shim has substantially uniform dimensions along a length of the wire or the flat shim.

FIG. 4 depicts a cross-sectional side view of a portion of a lamp housing 18 in accordance with at least some embodiments of the present disclosure. In some embodiments, a braze alloy 410 may be disposed about one or more of the plurality of tubes 21 adjacent an upper surface 414 of the copper plate 44. In some embodiments, the plurality of tubes 21 may be coupled to the copper plate 44 at a location vertically below the upper surface 414. For example, in some embodiments, the copper plate 44 includes an annular groove 426 in sidewalls 406 of each of the plurality of second openings 41 to accommodate a braze alloy 428. In some embodiments, for added strength, the plurality of tubes 21 are coupled to the copper plate 44 via both the braze alloy 410 and the braze alloy 428.

In some embodiments, the braze alloy 410 is in wire form. In some embodiments, the braze alloy 410 is 3D printed based on an actual outer diameter of each of the plurality of tubes 21 to advantageously ensure a good brazed joint. In some embodiments, the braze alloy 428 and is in wire form. In some embodiments, the braze alloy 428 is 3D printed based on actual dimensions of each of the annular grooves 426 to advantageously ensure a good brazed joint. In some embodiments, a braze alloy 432 may be disposed in the annular groove 214 of the copper plate 44 for accommodating coupling the annular jacket 220 to the copper plate 44. In some embodiments, the braze alloy 432 is disposed on a lower surface 440 of the annular groove. In some embodiments, the braze alloy 432 is in wire form, flat shim form, or a 3D printed part.

FIG. 6 depicts a cross-sectional side view of an interface 610 between an annular jacket 220 of a lamp housing 18 and a copper plate 44 of the lamp housing 18 in accordance with at least some embodiments of the present disclosure. In some embodiments, the annular jacket 220 is brazed to the copper plate 44 via the braze alloy 432 disposed in the annular groove 214. In some embodiments, the braze alloy 432 is disposed along an inner surface 606 of the annular groove 214, an outer surface 612 of the annular groove 214, and the lower surface 440 of the annular groove 214. In some embodiments, the copper plate 44 includes a second annular groove 608 disposed in the annular groove 214, for example, along the inner surface 606 or the outer surface 612 (along outer surface 612 as shown in FIG. 6). The braze alloy 432 may be disposed in the second annular groove 608. In some embodiments, the braze alloy 432 is in wire or flat shim form. In some embodiments, the braze alloy 432 is 3D printed.

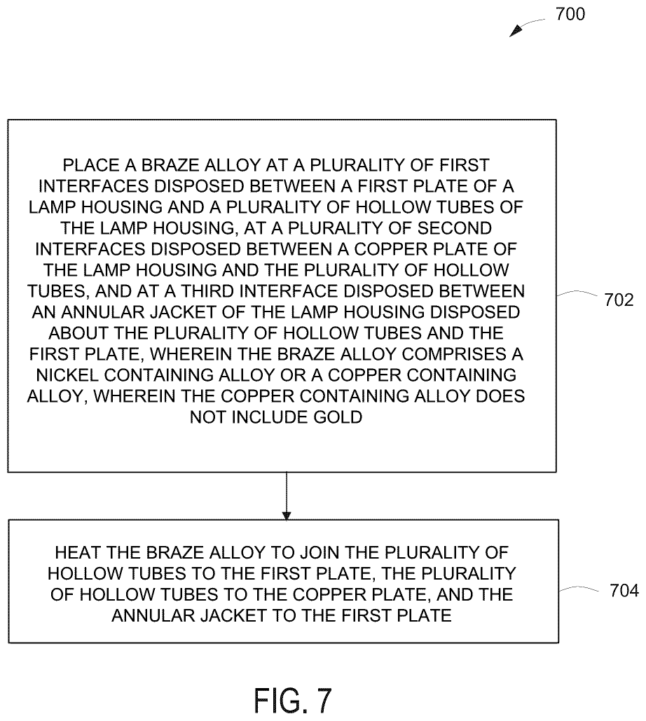

FIG. 7 depicts a flow chart of a method 700 of forming a lamp housing (e.g., lamp housing 18) for a process chamber (e.g., RTP chamber 100) in accordance with at least some embodiments of the present disclosure. At 702, the method 700 includes placing a braze alloy (e.g., braze alloy 346) at a plurality of first interfaces disposed between a top plate (e.g., top plate 206) of a lamp housing and a plurality of tubes (e.g., plurality of tubes 21) of the lamp housing. At 702, the method 700 further includes placing a braze alloy (e.g., braze alloy 410, braze alloy 428 at a plurality of second interfaces disposed between a copper plate (e.g., copper plate 44) of the lamp housing and the plurality of hollow tubes. At 702, the method 700 further includes placing a braze alloy (e.g., braze alloy 432) at a third interface disposed between an annular jacket (e.g., annular jacket 220) of the lamp housing disposed about the plurality of hollow tubes and the top plate.

The braze alloy is generally made of a material that is not susceptible to corrosion when coupled with copper and having a liquidus temperature less than a melting temperature of copper. For example, the braze alloy comprises a nickel containing alloy or a copper containing alloy, wherein the copper containing alloy does not include gold. In some embodiments, the braze alloy is a copper-germanium-nickel alloy having, by weight, about 60 to about 90 percent copper, about 5 to about 40 percent germanium, and about 0.1 to about 0.5 percent nickel.

In some embodiments, at least some of the braze alloy is in a wire form. In some embodiments, the method 700 includes forming a plurality of 3D printed braze parts comprising the braze alloy based on dimensions of the plurality of first interfaces, the plurality of second interfaces, and the third interface, and wherein placing the braze alloy includes placing corresponding ones of the plurality of 3D printed braze parts in corresponding ones of the plurality of first interfaces, the plurality of second interfaces, and the third interface. The dimensions of the plurality of first interfaces, the plurality of second interfaces, and the third interface may be obtained using any suitable technique.

In some embodiments, the plurality of second interfaces include respective annular grooves (e.g., annular groove 426) formed in the copper plate. In some embodiments, placing the braze alloy (e.g., braze alloy 428) at the plurality of second interfaces comprises placing the braze alloy in the annular grooves to form a stronger coupling therebetween. In some embodiments, the third interface includes an annular groove (e.g., second annular groove 608 formed in the copper plate. In some embodiments, the braze alloy (e.g., braze alloy 432) is disposed along two or more sides or surrounds portions of the annular jacket that extends into the second annular groove 608 to form better brazed joints with minimal or reduced voids and cracks formed in the brazed joints.

At 704, the method 700 includes heating the braze alloy to a suitable temperature to join the plurality of hollow tubes to the top plate, the plurality of hollow tubes to the copper plate, and the annular jacket to the top plate. For example, the braze alloy is heated to a temperature greater than a liquidus temperature of the braze alloy and less than the melting temperature of copper.

While the foregoing is directed to embodiments of the present disclosure, other and further embodiments of the disclosure may be devised without departing from the basic scope thereof.

1. A lamp housing for a process chamber, comprising:
a first plate having a plurality of first openings;
a copper plate having a plurality of second openings;
a plurality of tubes brazed via a braze alloy to the first plate at first ends of the plurality of tubes and brazed to the copper plate via the braze alloy at second ends of the plurality of tubes, wherein the plurality of tubes have central openings that are aligned with the plurality of first openings and the plurality of second openings, and wherein the braze alloy comprises a nickel containing alloy or a copper containing alloy, wherein the copper containing alloy does not include gold; and
an annular jacket circumscribing the plurality of tubes and brazed to the first plate via the braze alloy.

2. The lamp housing of claim 1, wherein the braze alloy comprises at least one of a wire form or flat shim form.

3. The lamp housing of claim 1, wherein the braze alloy comprises one of:
a titanium-nickel alloy;
a silver-copper-tin-titanium alloy;
a silver-copper-indium-titanium alloy;
a copper-manganese-nickel alloy;
a copper-germanium-nickel alloy;
a silver-copper-lead alloy; or
a gold-nickel alloy.

4. The lamp housing of claim 1, wherein a lower surface of the first plate includes a chamfer adjacent to an interface between the annular jacket and the first plate.

5. The lamp housing of claim 1, wherein the copper plate includes an annular groove in sidewalls of each of the plurality of second openings to accommodate the braze alloy.

6. The lamp housing of claim 1, wherein the copper plate includes an annular groove on an upper surface of the copper plate to accommodate the annular jacket.

7. The lamp housing of claim 6, wherein the annular jacket is brazed to the copper plate via the braze alloy disposed in the annular groove, wherein the braze alloy is disposed along an inner surface of the annular groove, an outer surface of the annular groove, and a lower surface of the annular groove.

8. The lamp housing of claim 1, wherein the first plate includes an annular groove to accommodate an upper lip of the annular jacket, and wherein the braze alloy disposed between the annular jacket and the first plate extends along an outer sidewall of the upper lip, a top surface of the upper lip, and an inner sidewall of the upper lip.

9. The lamp housing of claim 1, further comprising a bottom flange disposed about the copper plate and coupled to the copper plate.

10. A lamp housing for a process chamber, comprising:
a first plate made of a first material and having a plurality of first openings;
a copper plate having a plurality of second openings;
a plurality of tubes brazed via a braze alloy to the first plate at first ends of the plurality of tubes and brazed to the copper plate via the braze alloy at second ends of the plurality of tubes, wherein the plurality of tubes have central openings that are aligned with the plurality of first openings and the plurality of second openings, and wherein the braze alloy comprises a copper containing alloy and does not include gold; and
an annular jacket made of the first material and circumscribing the plurality of tubes and brazed to the first plate via the braze alloy and coupled to the copper plate.

11. The lamp housing of claim 10, wherein the braze alloy is a copper-germanium-nickel alloy having, by weight, about 60 to about 90 percent copper, about 5 to about 40 percent germanium, and about 0.1 to about 0.5 percent nickel.

12. The lamp housing of claim 10, wherein the first material does not include copper.

13. The lamp housing of claim 10, wherein the first material is stainless steel.

14. A rapid thermal processing chamber, comprising:
a chamber body defining an interior volume therein;
the lamp housing of claim 10 disposed in an upper portion of the interior volume;
a plurality of lamps disposed in the lamp housing; and
a substrate support disposed in the interior volume, wherein a quartz window is disposed between the plurality of lamps and the substrate support.

15. A method of forming a lamp housing for a process chamber, comprising:
placing a braze alloy at a plurality of first interfaces disposed between a first plate of a lamp housing and a plurality of hollow tubes of the lamp housing, at a plurality of second interfaces disposed between a copper plate of the lamp housing and the plurality of hollow tubes, and at a third interface disposed between an annular jacket of the lamp housing disposed about the plurality of hollow tubes and the first plate, wherein the braze alloy comprises a nickel containing alloy or a copper containing alloy, wherein the copper containing alloy does not include gold; and
heating the braze alloy to join the plurality of hollow tubes to the first plate, the plurality of hollow tubes to the copper plate, and the annular jacket to the first plate.

16. The method of claim 15, further comprising forming a plurality of 3D printed braze parts comprising the braze alloy based on dimensions of the plurality of first interfaces, the plurality of second interfaces, and the third interface, and wherein placing the braze alloy includes placing corresponding ones of the plurality of 3D printed braze parts in corresponding ones of the plurality of first interfaces, the plurality of second interfaces, and the third interface.

17. The method of claim 15, wherein at least some of the braze alloy is in a wire form.

18. The method of claim 15, wherein the braze alloy is a copper-germanium-nickel alloy having, by weight, about 60 to about 90 percent copper, about 5 to about 40 percent germanium, and about 0.1 to about 0.5 percent nickel.

19. The method of claim 15, wherein the plurality of second interfaces include an annular groove formed in the copper plate, and wherein placing the braze alloy at the plurality of second interfaces comprises placing the braze alloy in the annular groove.

20. The method of claim 15, wherein the braze alloy does not include copper.
